(19) United States
(12) Patent Application Publication
(10) Pub. No.: US 2025/0343150 A1
(43) Pub. Date: Nov. 6, 2025

(54) SEMICONDUCTOR STRUCTURE INCLUDING CONDUCTIVE FEATURE WITH SEMIMETAL PORTION AND METHOD FOR MANUFACTURING THE SAME

(71) Applicant: TAIWAN SEMICONDUCTOR MANUFACTURING COMPANY, LTD., Hsinchu (TW)

(72) Inventors: Shu-Wei LI, Hsinchu (TW); Yu-Chen CHAN, Hsinchu (TW); Shin-Yi YANG, Hsinchu (TW); Ming-Han LEE, Hsinchu (TW)

(73) Assignee: TAIWAN SEMICONDUCTOR MANUFACTURING COMPANY, LTD., Hsinchu (TW)

(21) Appl. No.: 18/654,198

(22) Filed: May 3, 2024

(51) Int. Cl. H01L 23/535; H01L 21/768; H01L 23/532

(52) U.S. Cl. CPC H01L 23/535; H01L 21/76886; H01L 21/76895; H01L 23/53204

(57) ABSTRACT

A semiconductor structure includes a substrate, a dielectric structure, and an interconnect structure. The dielectric structure includes a first dielectric layer disposed on the substrate and a second dielectric layer disposed on the first dielectric layer opposite to the substrate. The interconnect structure is configured with a first conductive feature disposed in the first dielectric layer, and a second conductive feature disposed in the second dielectric layer and connected to the first conductive feature, and includes a first metal material portion, a two-dimensional material portion and a first semimetal material portion disposed between and connected to the first metal material portion and the two-dimensional material portion.

### BACKGROUND

A continual reduction in minimum feature sizes of an integrated circuit (IC) chip is a trend in the semiconductor industry. Since the features of an IC chip are being scaled down, functional density (i.e., the number of semiconductor devices per chip area) of the IC chip can be increased, and thus the economic benefit of the IC chip can be increased. However, some issues, such as a high contact resistance, may occur with the scaling down of the feature sizes of the IC chip, which may adversely affect chip performance of the IC chip.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 7 are schematic views illustrating some intermediate stages of the method as depicted in FIG. 1 in accordance with some embodiments.

FIGS. 8 to 39 are schematic views respectively illustrating a plurality of the semiconductor structures obtained by the method as depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

In an interconnect structure of a semiconductor device (e.g., a semiconductor integrated circuit chip), a metal feature, which serves as a major conductor within the interconnect structure, is usually made of copper. As a dimension of the semiconductor device shrinks, some issues that arise, for example, an increase in the resistivity of the metal feature when the size of the metal feature is reduced, which may adversely affect device performance of the semiconductor device, need to be solved. A two-dimensional (2D) material with anisotropic conductivity has been included in the interconnect structure of the semiconductor device to reduce the increased resistivity of the metal feature having a reduced size. However, when the 2D material is in contact with the metal feature, a high contact resistance may be induced between the 2D material and the metal feature due to poor carrier injection efficiency of the 2D material resulting from the presence of a carrier/electron transport barrier, which may also adversely affect the device performance of the semiconductor device. Therefore, there is a need to reduce the carrier/electron transport barrier between the metal feature and the 2D material.

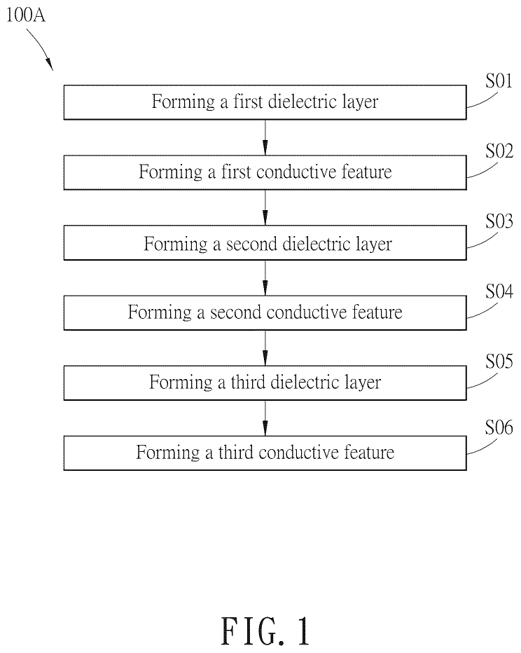

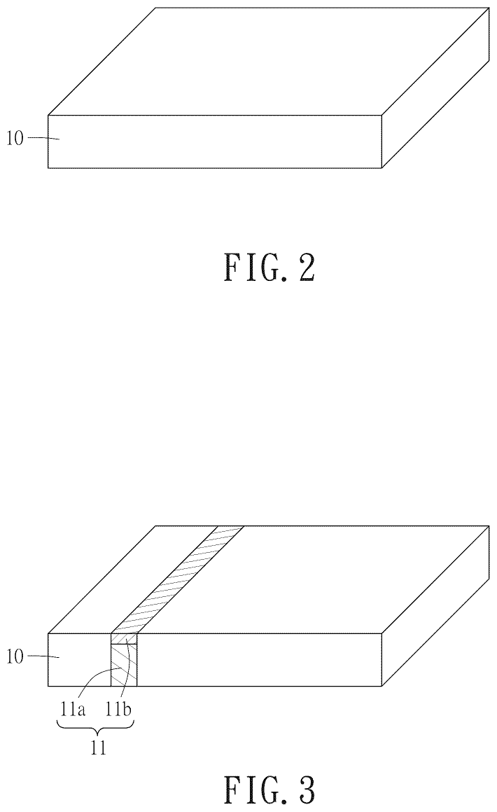

The present disclosure is directed to a semiconductor structure and a method for manufacturing the same. FIG. 1 is a flow diagram illustrating a method 100A for manufacturing a semiconductor structure 200A shown in FIG. 7 in accordance with some embodiments. FIGS. 2 to 6 illustrate schematic views of some intermediate stages of the method 100A. Some portions may be omitted in FIGS. 2 to 6 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a first dielectric layer 10 is formed on a substrate (not shown). In some embodiments, the substrate may be, for example, but not limited to, a semiconductor substrate. In some embodiments, the first dielectric layer 10 may be made of a low-dielectric constant (k) material, for example, but not limited to, carbon-doped silicon oxide, Xerogel, Aerogel, fluorosilicate glass (FSG), amorphous fluorinated carbon, Parylene, polyimide, benzocyclobutene (BCB), or combinations thereof. Other suitable low-k materials for the first dielectric layer 10 are within the contemplated scope of the present disclosure. In some embodiments, the k value of the low-k material for forming the first dielectric layer 10 may range from about 1 to about 3.9. The first dielectric layer 10 may be formed by a suitable deposition process, for example, but not limited to, chemical vapor deposition (CVD), physical vapor deposition (PVD), or other suitable deposition processes.

Referring to FIG. 1 and the example illustrated in FIG. 3, the method 100A then proceeds to step S02, where a first conductive feature 11 (for example, but not limited to, a contact via) is formed in the first dielectric layer 10. Step S02 may include sub-steps (i) to (iii).

In sub-step (i), the first dielectric layer 10 may be patterned by photolithography, which includes an etching process. The photolithography may include, for example, but not limited to, coating a photoresist on the first dielectric layer 10, soft-baking the photoresist, exposing the photoresist through a photomask, post-exposure baking the photoresist, and developing the photoresist, followed by hard-baking the photoresist so as to form a patterned photoresist on the first dielectric layer 10. In the etching process, the first dielectric layer 10 may be etched by a suitable etching process (for example, but not limited to, dry etching, wet etching, a combination thereof, or other suitable etching processes) using the patterned photoresist as a patterned mask, so as to form a recess (not shown) in the first dielectric layer 10. The patterned photoresist is then removed by, for example, but not limited to, an ashing process or other suitable removal processes after the first dielectric layer 10 is formed with the recess.

In sub-step (ii), a metal material portion 11a is formed to partially fill the recess by a suitable selective deposition process (for example, but not limited to, CVD, PVD, atomic layer deposition (ALD), electrochemical plating (ECP), electrochemical deposition (ECD), electroless deposition (ELD), or other suitable deposition processes). The metal material portion 11a may be made of a metal material that includes, for example, but not limited to, cobalt, copper, nickel, ruthenium, tungsten, molybdenum, titanium, zirconium, tantalum, zinc, and combinations thereof. Other suitable metal materials for forming the metal material portion 11a are within the contemplated scope of the present disclosure. In some embodiments, the metal material portion 11a may have a thickness ranging from about 50 Å to about 20000 Å. If the thickness of the metal material portion 11a is less than about 50 Å, a capacitance formed between a conductive structure (not shown) below the metal material portion 11a and a second conductive feature 21 (see FIG. 5) may be increased, which may adversely affect electrical performance of the semiconductor structure 200A. If the thickness of the metal material portion 11a is greater than about 20000 Å, a difficulty in formation of the metal material portion 11a may be increased.

In sub-step (iii), a semimetal material portion 11b is formed on the metal material portion 11a so as to fully fill the recess by a suitable selective deposition process (for example, but not limited to, CVD, PVD, ALD, ELD, ECP, ECD, or other suitable deposition processes). The semimetal material portion 11b may be made of a semimetal material that includes, for example, but not limited to, bismuth, antimony, arsenic, tin (e.g., alpha-Sn), and combinations thereof. After this sub-step, the first conductive feature 11 is formed in the first dielectric layer 10, and includes the metal material portion 11a and the semimetal material portion 11b.

In some embodiments, after formation of the recess of the first dielectric layer 10 (i.e., sub-step (i) of step S02) and before formation of the metal material portion 11a (i.e., sub-step (ii) of step S02), a first barrier/liner layer (not shown) may be conformally formed in the recess. In some embodiments, the first barrier/liner layer may include a first barrier sublayer and a first liner sublayer. In some embodiments, the first barrier sublayer may include, for example, but not limited to, silicon nitride, silicon oxide, ruthenium, cobalt, titanium, titanium nitride, tantalum, tantalum nitride, transition metal dichalcogenide (TMD), or combinations thereof. In some embodiments, the first liner sublayer may include, for example, but not limited to, titanium, titanium nitride, ruthenium, tantalum, tantalum nitride, cobalt, nickel, copper, tungsten, tungsten nitride, tungsten carbide, or combinations thereof.

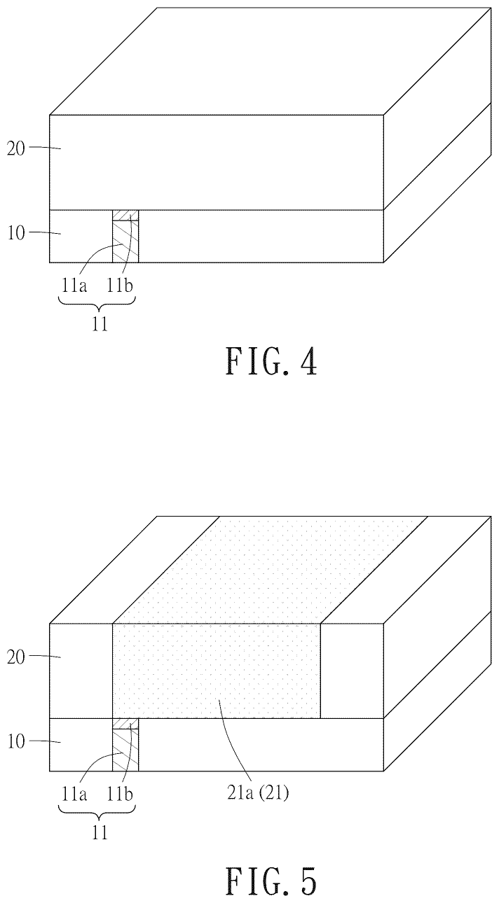

Referring to FIG. 1 and the example illustrated in FIG. 4, the method 100A then proceeds to step S03, where a second dielectric layer 20 is formed on the first dielectric layer 10 and the first conductive feature 11. The material and process for forming the second dielectric layer 20 may be the same as or similar to those for forming the first dielectric layer 10, and thus details thereof are omitted for the sake of brevity.

Referring to FIG. 1 and the example illustrated in FIG. 5, the method 100A then proceeds to step S04, where the second conductive feature 21 is formed in the second dielectric layer 20. The process for forming the second conductive feature 21 in the second dielectric layer 20 may be similar to that for forming the first conductive feature 11 in the first dielectric layer 10 (as described in step S02), except that the second conductive feature 21 includes a two-dimensional (2D) material portion 21a. In some embodiments, the 2D material portion 21a may be formed by, for example, but not limited to, a selective deposition process or a transfer process. In some embodiments, the selective deposition process may be, for example, but not limited to, thermal CVD, plasma-enhanced CVD (PECVD), ALD, PVD, or other suitable deposition processes. The 2D material portion 21a may include a two-dimensional (2D) material optionally intercalated with at least one intercalation component. In some embodiments, the 2D material may be, for example, but not limited to, TMD, graphene, phosphorene, Xenes (e.g., borophene, silicene, germanene, stanene, arsenene, antimonene, bismuthene, tellurene, or combinations thereof), or combinations thereof. In some embodiments, the 2D material portion 21a may be formed as a single layer structure or a multi-layered structure. In some embodiments, the 2D material portion 21a may have a thickness ranging from about 3 Å to about 10000 Å. If the thickness of the 2D material portion 21a is greater than about 10000 Å, a difficulty in formation of the 2D material portion 21a may be increased. In some embodiments, intercalation of the at least one intercalation component between the layers of the 2D material portion 21a may be performed using a vacuum CVD system or a liquid electrolysis system. In some embodiments, the at least one intercalation component may include, for example, but not limited to, metal material (e.g., lithium, potassium, cesium, sodium, or combinations thereof), metal complex, organic material (e.g., benzene, pyridine, furan, catechol, tetracyanoquinodimethane (TCNQ), tetrathiafulvalence (TTF), or combinations thereof), inorganic material (e.g., ferric chloride, molybdenum pentachloride, auric chloride, cupric chloride, sulfuric acid, aluminum chloride, bromine, chlorine, nitric acid, or combinations thereof), or combinations thereof. In some embodiments, when the second conductive feature 21 includes a plurality of sets of the 2D materials that are arranged in layers with a layer of the at least one intercalation component being intercalated between two adjacent sets of the 2D materials, a layer number of the 2D materials in each set of the 2D materials may range from about 1 to about 10. After this step, the second conductive feature 21 is connected to the first conductive feature 11, and the semimetal material portion 11b is disposed between and in direct contact with the metal material portion 11a and the 2D material portion 21a.

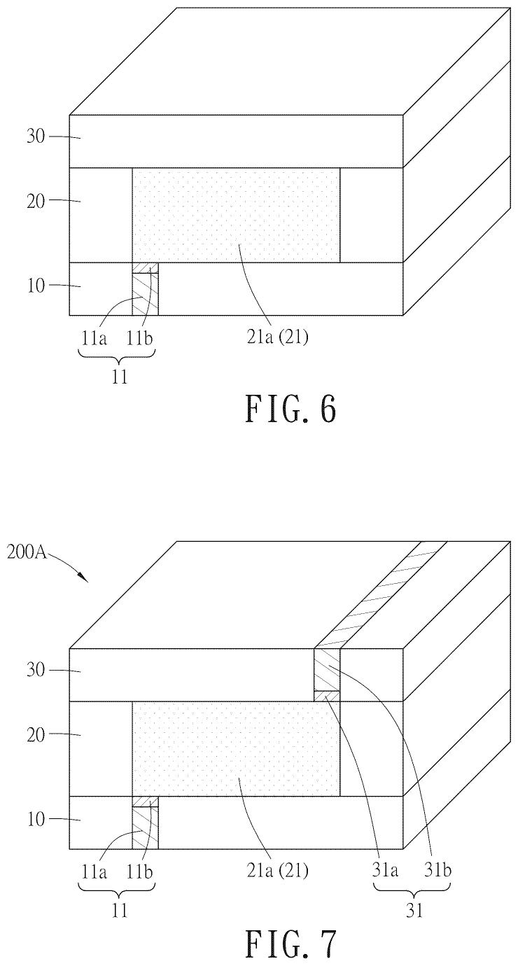

Referring to FIG. 1 and the example illustrated in FIG. 6, the method 100A then proceeds to step S05, where a third dielectric layer 30 is formed on the second dielectric layer 20 and the second conductive feature 21. The material and process for forming the third dielectric layer 30 may be the same as or similar to those for forming the first dielectric layer 10, and thus details thereof are omitted for the sake of brevity.

Referring to FIG. 1 and the example illustrated in FIG. 7, the method 100A then proceeds to step S06, where a third conductive feature 31 is formed in the third dielectric layer 30. The material and process for forming the third conductive feature 31 may be the same as or similar to those for forming the first conductive feature 11, and thus details thereof are omitted for the sake of brevity. After this step, the third conductive feature 31 is formed to include a semimetal material portion 31a disposed on the 2D material portion 21a, and a metal material portion 31b disposed on the semimetal material portion 31a. The third conductive feature 31 is connected to the second conductive feature 21, and the semimetal material portion 31a is disposed between and in direct contact with the metal material portion 31b and the 2D material portion 21a.

In some embodiments, before formation of the third conductive feature 31, a second barrier/liner layer (not shown) may be formed in a recess (not shown) of the third dielectric layer 30 for forming the third conductive feature 31, so that after the formation of the third conductive feature 31, the second barrier/liner layer may laterally cover two opposite sides of the third conductive feature 31. The material and process for forming the second barrier/liner layer may be the same as or similar to those for forming the first barrier/liner layer, and thus details thereof are omitted for the sake of brevity.

After step S06, the semiconductor structure 200A is obtained. By having the semimetal material portion 11b disposed between the metal material portion 11a and the 2D material portion 21a, and the semimetal material portion 31a disposed between the metal material portion 31b and the 2D material portion 21a, a contact resistance (Rc) between the metal material portion 11a and the 2D material portion 21a and a contact resistance (Rc) between the 2D material portion 21a and the metal material portion 31b may be reduced, which is conducive to enhancing electrical performance of the semiconductor structure 200A. The first conductive feature 11, the second conductive feature 21, and the third conductive feature 31 may be collectively referred to as an interconnect structure.

As described above, each of the first conductive feature 11, the second conductive feature 21, and the third conductive feature 31 is illustrated to be formed by a single damascene process. In some embodiments, the first conductive feature 11 and the second conductive feature 21 may be formed together by a dual damascene process.

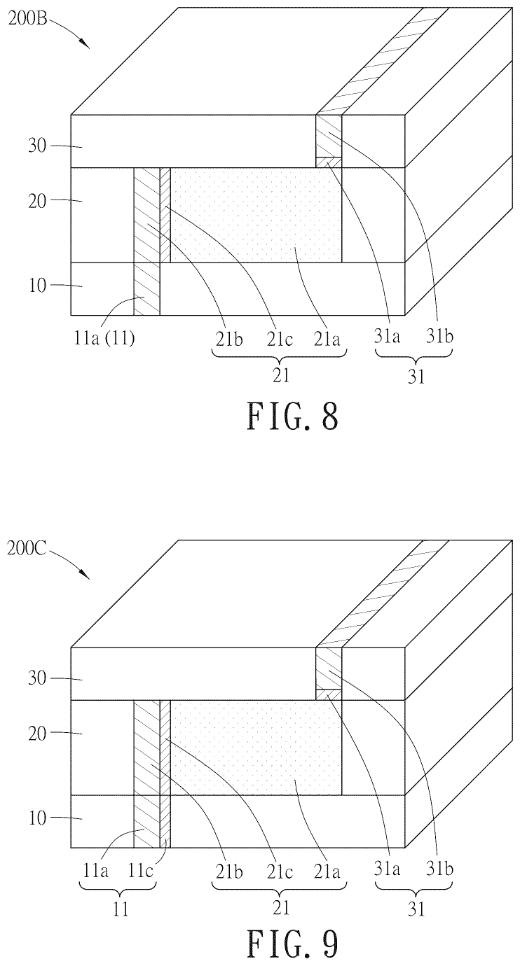

FIG. 8 illustrates a schematic view of a semiconductor structure 200B in accordance with some embodiments. A configuration of the semiconductor structure 200B is similar to that of the semiconductor structure 200A except that, in the semiconductor structure 200B, the first conductive feature 11 includes the metal material portion 11a without the semimetal material portion 11b, and the second conductive feature 21 includes the 2D material portion 21a, a metal material portion 21b and a semimetal material portion 21c that is disposed between and in direct contact with the 2D material portion 21a and the metal material portion 21b. A method for manufacturing the semiconductor structure 200B is similar to the method 100A, except that, in formation of the first conductive feature 11, the metal material portion 11a is formed to fully fill the recess of the first dielectric layer 10, and that in formation of the second conductive feature 21, the 2D material portion 21a, the semimetal material portion 21c, and the metal material portion 21b are formed in a recess of the second dielectric layer 20 so as to configure the second conductive feature 21. It is noted that there is no particular limitation on a sequence of formation of the 2D material portion 21a, the semimetal material portion 21c, and the metal material portion 21b in the recess of the second dielectric layer 20.

FIG. 9 illustrates a schematic view of a semiconductor structure 200C in accordance with some embodiments. A configuration of the semiconductor structure 200C is similar to that of the semiconductor structure 200B (see FIG. 8) except that, in the semiconductor structure 200C, the first conductive feature 11 further includes a semimetal material portion 11c that is disposed between the first dielectric layer 10 and the metal material portion 11a and that is connected to the semimetal material portion 21c. The material for the semimetal material portion 11c may be the same as or similar to that for the semimetal material portion 11b (as described in step S2), and thus details thereof are omitted for the sake of brevity. In some embodiments, the semimetal material portion 11c may be formed in the recess of the first dielectric layer 10 after formation of the recess of the first dielectric layer 10 (i.e., sub-step (i) of step S02) and before formation of the metal material portion 11a (i.e., sub-step (ii) of step S02).

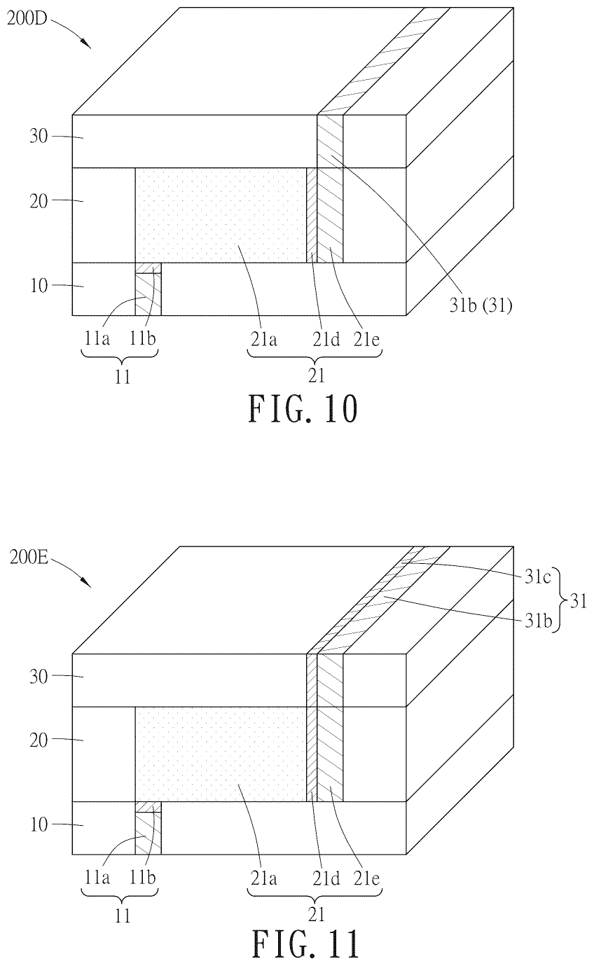

FIG. 10 illustrates a schematic view of a semiconductor structure 200D in accordance with some embodiments. A configuration of the semiconductor structure 200D is similar to that of the semiconductor structure 200A (see FIG. 7) except that, in the semiconductor structure 200D, the second conductive feature 21 further includes a semimetal material portion 21d and a metal material portion 21e, and the third conductive feature 31 includes the metal material portion 31b without the semimetal material portion 31a. In this case, the semimetal material portion 21d is disposed between and in direct contact with the 2D material portion 21a and the metal material portion 21e. The material for each of the semimetal material portion 21d and the metal material portion 21e may be the same as or similar to that for a corresponding one of the semimetal material portion 11b and the metal material portion 11a (as described in step S2), and thus details thereof are omitted for the sake of brevity. The semimetal material portion 21d and the metal material portion 21e may be formed in the recess of the second dielectric layer 20 after formation of the recess of the second dielectric layer 20. It is noted that there is no particular limitation on a sequence of formation of the 2D material portion 21a, the semimetal material portion 21d, and the metal material portion 21e in the recess of the second dielectric layer 20.

FIG. 11 illustrates a schematic view of a semiconductor structure 200E in accordance with some embodiments. A configuration of the semiconductor structure 200E is similar to that of the semiconductor structure 200D (see FIG. 10) except that, in the semiconductor structure 200E, the third conductive feature 31 further includes a semimetal material portion 31c that is disposed between the third dielectric layer 30 and the metal material portion 31b and that is connected to the semimetal material portion 21d. The material for the semimetal material portion 31c may be the same as or similar to that for the semimetal material portion 11b (as described in step S02), and thus details thereof are omitted for the sake of brevity. The semimetal material portion 31c may be formed in the recess of the third dielectric layer 30 after formation of the recess of the third dielectric layer 30 and before formation of the metal material portion 31b.

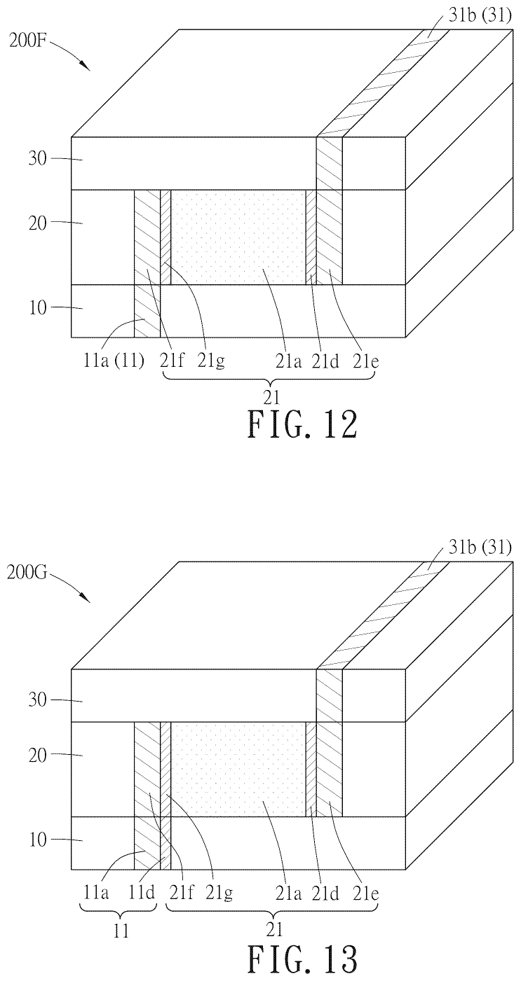

FIG. 12 illustrates a schematic view of a semiconductor structure 200F in accordance with some embodiments. A configuration of the semiconductor structure 200F is similar to that of the semiconductor structure 200D (see FIG. 10) except for the following differences. In the semiconductor structure 200F, the first conductive feature 11 includes the metal material portion 11a without any semimetal material portion and an upper surface of the metal material portion 11a is in contact with a lower surface of the second conductive feature 21, and the second conductive feature 21 further includes a metal material portion 21f and a semimetal material portion 21g. In this case, the semimetal material portion 21g is disposed between and in direct contact with the metal material portion 21f and the 2D material portion 21a. The material and process for each of the metal material portion 21f and the semimetal material portion 21g are similar to those for a corresponding one of the metal material portion 21e and the semimetal material portion 21d, and thus details thereof are omitted for the sake of brevity. It is noted that there is no particular limitation on a sequence of formation of the 2D material portion 21a, the semimetal material portion 21d, the metal material portion 21e, the metal material portion 21f, and the semimetal material portion 21g in the recess of the second dielectric layer 20. In some embodiments, the metal material portion 21e and the metal material portion 21f may be simultaneously formed. In some embodiments, the semimetal material portion 21d and the semimetal material portion 21g may be simultaneously formed.

FIG. 13 illustrates a schematic view of a semiconductor structure 200G in accordance with some embodiments. A configuration of the semiconductor structure 200G is similar to that of the semiconductor structure 200F (see FIG. 12) except that, in the semiconductor structure 200G, the first conductive feature 11 further includes a semimetal material portion 11d that is disposed between the first dielectric layer 10 and the metal material portion 11a and that is connected to the semimetal material portion 21g. The material for the semimetal material portion 11d may be the same as or similar to that for the semimetal material portion 11b (as described in step S02), and thus details thereof are omitted for the sake of brevity. In some embodiments, the semimetal material portion 11d may be formed in the recess of the first dielectric layer 10 after the formation of the recess of the first dielectric layer 10 and before the formation of the metal material portion 11a.

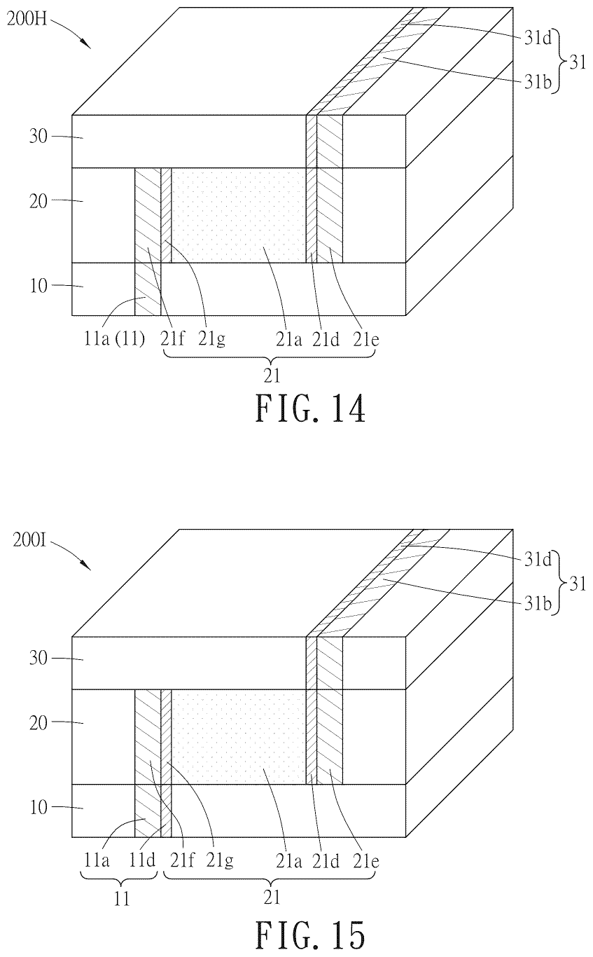

FIG. 14 illustrates a schematic view of a semiconductor structure 200H in accordance with some embodiments. A configuration of the semiconductor structure 200H is similar to that of the semiconductor structure 200F (see FIG. 12) except that, in the semiconductor structure 200H, the third conductive feature 31 further includes a semimetal material portion 31d that is disposed between the third dielectric layer 30 and the metal material portion 31b and that is connected to the semimetal material portion 21d. The material for the semimetal material portion 31d may be the same as or similar to that for the semimetal material portion 31a (as described in step S06), and thus details thereof are omitted for the sake of brevity. In some embodiments, the semimetal material portion 31d may be formed in the recess of the third dielectric layer 30 after the formation of the recess of the third dielectric layer 30 and before the formation of the metal material portion 31b.

FIG. 15 illustrates a schematic view of a semiconductor structure 200I in accordance with some embodiments. A configuration of the semiconductor structure 200I is similar to that of the semiconductor structure 200F (see FIG. 12) except that, in the semiconductor structure 200I, the first conductive feature 11 further includes the semimetal material portion 11d (see FIG. 13), and the third conductive feature 31 further includes the semimetal material portion 31d (see FIG. 14). The material and process for each of the semimetal material portion 11d and the semimetal material portion 31d are described in the foregoing paragraphs, and thus details thereof are omitted for the sake of brevity.

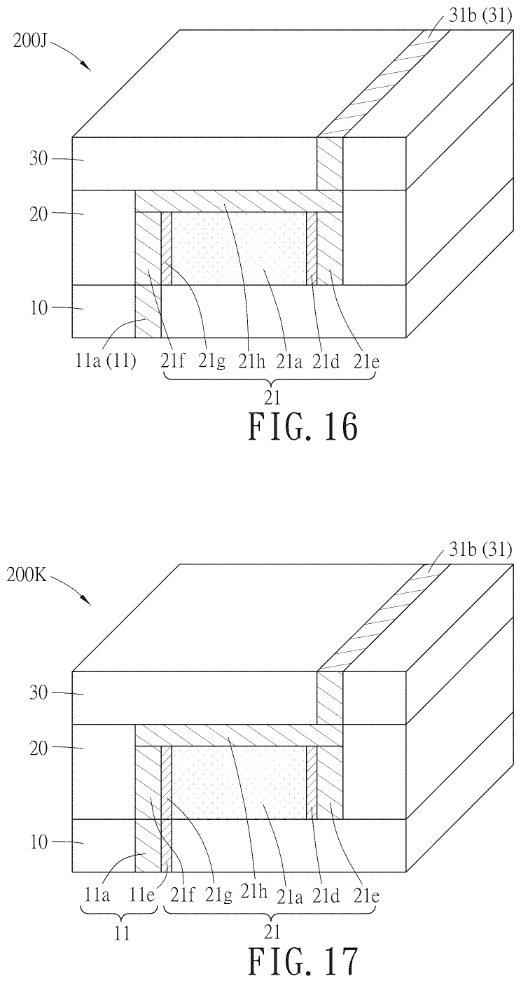

FIG. 16 illustrates a schematic view of a semiconductor structure 200J in accordance with some embodiments. A configuration of the semiconductor structure 200J is similar to that of the semiconductor structure 200F (see FIG. 12) except that, the second conductive feature 21 further includes a metal material portion 21h disposed in the second dielectric layer 20 and on the metal material portions 21e, 21f, the semimetal material portions 21d, 21g, and the 2D material portion 21a. In this case, a lower surface of the metal material portion 21h is in direct contact with an upper surface of the metal material portion 21e, an upper surface of the semimetal material portion 21d, an upper surface of the 2D material portion 21a, an upper surface of the semimetal material portion 21g, and an upper surface of the metal material portion 21f. The metal material portion 21h may be formed to fully fill the recess of the second dielectric layer 20 after formation of the 2D material portion 21a, the semimetal material portion 21d, the metal material portion 21e, the metal material portion 21f, and the semimetal material portion 21g, and before formation of the third dielectric layer 30 (i.e., step S05).

FIG. 17 illustrates a schematic view of a semiconductor structure 200K in accordance with some embodiments. A configuration of the semiconductor structure 200K is similar to that of the semiconductor structure 200J (see FIG. 16) except that, the first conductive feature 11 further includes a semimetal material portion 11e that is disposed between the first dielectric layer 10 and the metal material portion 11a, and that is connected to the semimetal material portion 21g. The material for the semimetal material portion 11e may be the same as or similar to that for the semimetal material portion 11b (as described in step S2), and thus details thereof are omitted for the sake of brevity. The semimetal material portion 11e may be formed in the recess of the first dielectric layer 10 after formation of the recess of the first dielectric layer 10 and before formation of the metal material portion 11a.

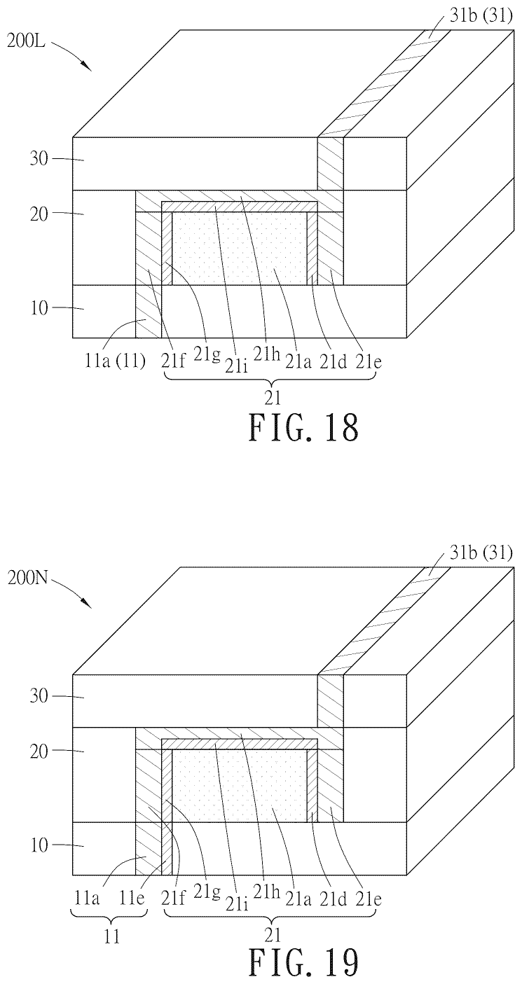

FIG. 18 illustrates a schematic view of a semiconductor structure 200L in accordance with some embodiments. A configuration of the semiconductor structure 200L is similar to that of the semiconductor structure 200J (see FIG. 16) except that, the second conductive feature 21 further includes a semimetal material portion 21i disposed between the metal material portion 21h and the 2D material portion 21a. The material for the semimetal material portion 21i may be the same as or similar to that for the semimetal material portion 11b (as described in step S2), and thus details thereof are omitted for the sake of brevity. The semimetal material portion 21i may be formed in the recess of the second dielectric layer 20 after the formation of the 2D material portion 21a, the semimetal material portion 21d and the semimetal material portion 21g, and before the formation of the third dielectric layer 30.

FIG. 19 illustrates a schematic view of a semiconductor structure 200N in accordance with some embodiments. A configuration of the semiconductor structure 200N is similar to that of the semiconductor structure 200J (see FIG. 16) except that, the first conductive feature 11 further includes the semimetal material portion 11e (see FIG. 17), and the second conductive feature 21 further includes the semimetal material portion 21i (see FIG. 18). The material and process for each of the semimetal material portion 11e and the semimetal material portion 21i are described in the foregoing paragraphs, and thus details thereof are omitted for the sake of brevity.

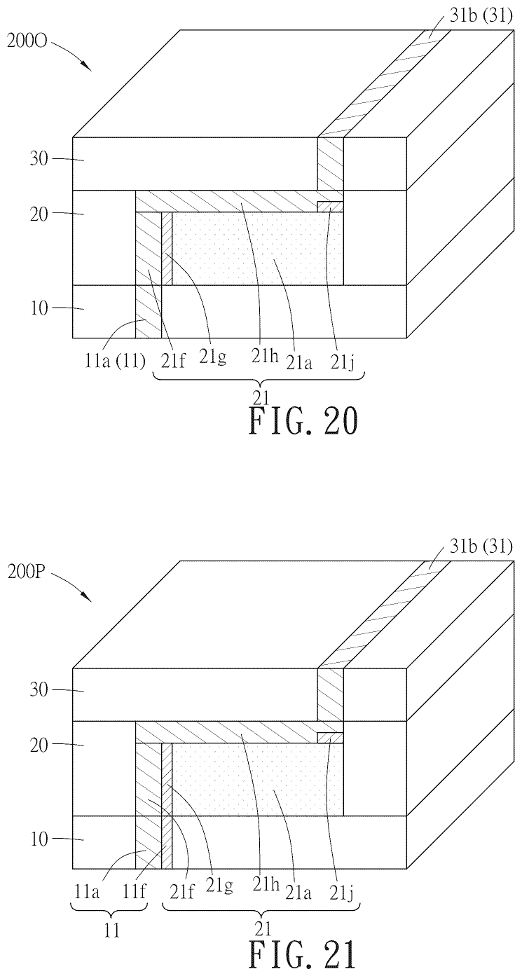

FIG. 20 illustrates a schematic view of a semiconductor structure 2000 in accordance with some embodiments. A configuration of the semiconductor structure 2000 is similar to that of the semiconductor structure 200J (see FIG. 16) except that, the second conductive feature 21 includes the 2D material portion 21a, the metal material portion 21f, the semimetal material portion 21g, the metal material portion 21h, and a semimetal material portion 21j without the semimetal material portion 21d and the metal material portion 21e. The semimetal material portion 21j is disposed between and in direct contact with the 2D material portion 21a and the metal material portion 21h. The material for the semimetal material portion 21j may be the same as or similar to that for the semimetal material portion 11b (as described in step S2), and thus details thereof are omitted for the sake of brevity. The metal material portion 21h is disposed on the 2D material portion 21a, the metal material portion 21f, and the semimetal material portion 21g. In this case, the semimetal material portion 21j may be selectively formed on the 2D material portion 21a after the formation of the 2D material portion 21a and before formation of the metal material portion 21h.

FIG. 21 illustrates a schematic view of a semiconductor structure 200P in accordance with some embodiments. A configuration of the semiconductor structure 200P is similar to that of the semiconductor structure 2000 (see FIG. 20) except that, the first conductive feature 11 further includes a semimetal material portion 11f that is disposed between the first dielectric layer 10 and the metal material portion 11a and that is connected to the semimetal material portion 21g. The material for the semimetal material portion 11f may be the same as or similar to that for the semimetal material portion 11b (as described in step S2), and thus details thereof are omitted for the sake of brevity.

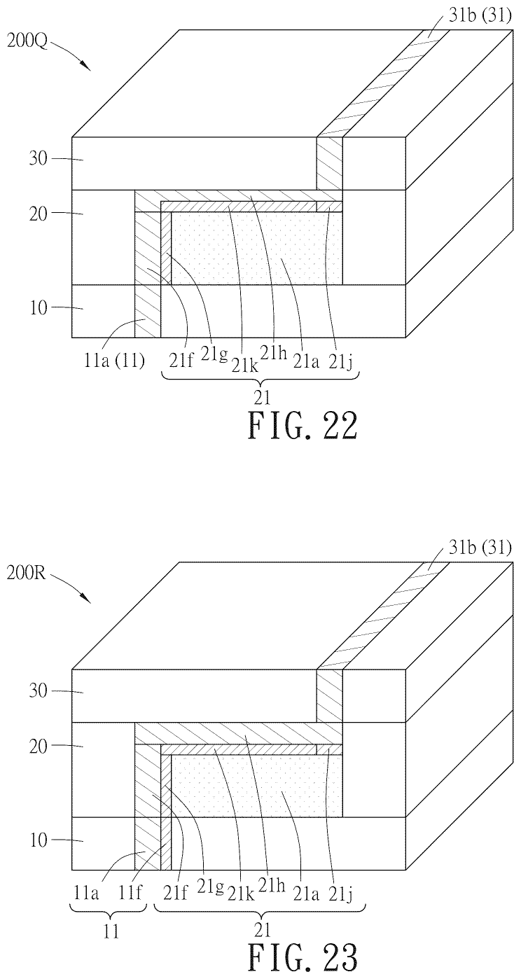

FIG. 22 illustrates a schematic view of a semiconductor structure 200Q in accordance with some embodiments. A configuration of the semiconductor structure 200Q is similar to that of the semiconductor structure 2000 (see FIG. 20) except that, the second conductive feature 21 further includes a semimetal material portion 21k that is disposed above and in direct contact with the 2D material portion 21a and the semimetal material portion 21g, and that is disposed below and in direct contact with the metal material portion 21h. The material for the semimetal material portion 21k may be the same as or similar to that for the semimetal material portion 11b (as described in step S2), and thus details thereof are omitted for the sake of brevity. In some embodiments, the semimetal material portion 21k may be selectively formed on the 2D material portion 21a and the semimetal material portion 21g and in the recess of the second dielectric layer 20, and before the formation of the metal material portion 21h. In some embodiments, the semimetal material portion 21k and the semimetal material portion 21j may be formed simultaneously.

FIG. 23 illustrates a schematic view of a semiconductor structure 200R in accordance with some embodiments. A configuration of the semiconductor structure 200R is similar to that of the semiconductor structure 2000 (see FIG. 20) except that, the first conductive feature 11 further includes the semimetal material portion 11f (see FIG. 21), and the second conductive feature 21 further includes the semimetal material portion 21k (see FIG. 22). The material and process for each of the semimetal material portion 11f and the semimetal material portion 21k are described in the foregoing paragraphs, and thus details thereof are omitted for the sake of brevity.

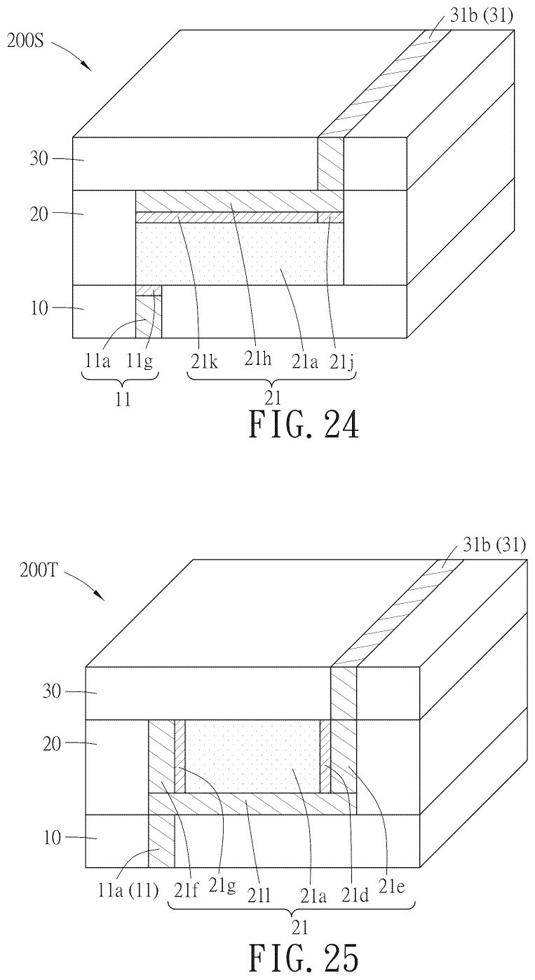

FIG. 24 illustrates a schematic view of a semiconductor structure 200S in accordance with some embodiments. A configuration of the semiconductor structure 200S is similar to that of the semiconductor structure 2000 (see FIG. 20) except that, the first conductive feature 11 includes the metal material portion 11a and a semimetal material portion 11g, and the second conductive feature 21 includes the 2D material portion 21a, the metal material portion 21h, the semimetal material portion 21j and the semimetal material portion 21k (see FIG. 22) without the metal material portion 21f and the semimetal material portion 21g. The semimetal material portion 11g is disposed between and in direct contact with the 2D material portion 21a and the metal material portion 11a. The semimetal material portion 21k is connected to the semimetal material portion 21j. The semimetal material portion 21k and the semimetal material portion 21j are disposed between and in direct contact with the 2D material portion 21a and the metal material portion 21h. The material and process for the semimetal material portion 11g may be the same as or similar to those for the semimetal material portion 11b (as described in step S2), and thus details thereof are omitted for the sake of brevity.

FIG. 25 illustrates a schematic view of a semiconductor structure 200T in accordance with some embodiments. A configuration of the semiconductor structure 200T is similar to that of the semiconductor structure 200F (see FIG. 12) except that, the second conductive feature 21 further includes a metal material portion 211 disposed below and in direct contact with the 2D material portion 21a, the semimetal material portion 21d, the metal material portion 21e, the metal material portion 21f, and the semimetal material portion 21g. The material for the metal material portion 211 may be the same as or similar to that for the metal material portion 11a (as described in step S02), and thus details thereof are omitted for the sake of brevity. The metal material portion 211 may be formed in the recess of the second dielectric layer 20 before formation of other portions (e.g., the 2D material portion 21a, etc.) of the second conductive feature 21.

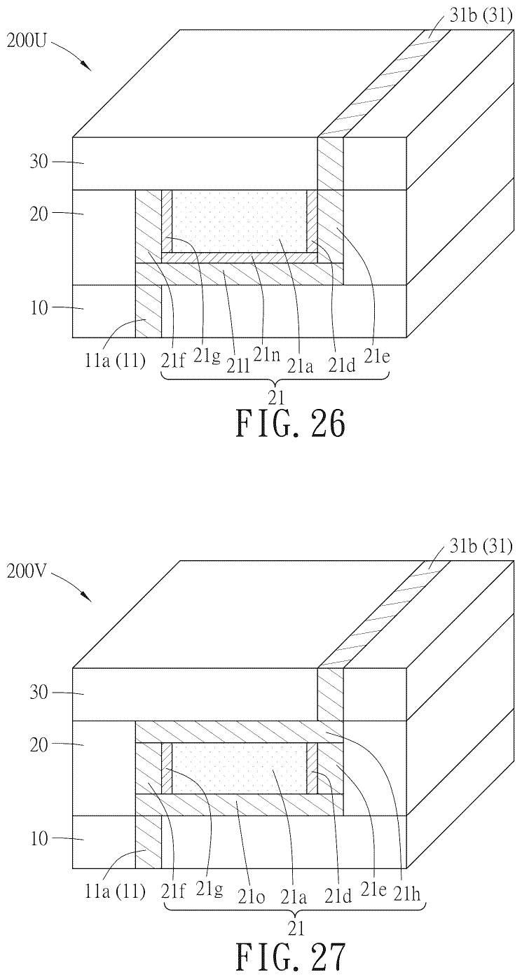

FIG. 26 illustrates a schematic view of a semiconductor structure 200U in accordance with some embodiments. A configuration of the semiconductor structure 200U is similar to that of the semiconductor structure 200T (see FIG. 25) except that, the second conductive feature 21 further includes a semimetal material portion 21n that is disposed below and in direct contact with the 2D material portion 21a, the semimetal material portion 21d and the semimetal material portion 21g, and that is disposed above and in direct contact with the metal material portion 211. The material for the semimetal material portion 21n may be the same as or similar to that for the semimetal material portion 11b (as described in step S02), and thus details thereof are omitted for the sake of brevity. In some embodiments, the semimetal material portion 21n may be selectively formed on the metal material portion 211 and in the recess of the second dielectric layer 20 after formation of the metal material portion 211 and before formation of other portions (e.g., the 2D material portion 21a, etc.) of the second conductive feature 21.

FIG. 27 illustrates a schematic view of a semiconductor structure 200V in accordance with some embodiments. A configuration of the semiconductor structure 200V is similar to that of the semiconductor structure 200J (see FIG. 16) except that, the second conductive feature 21 further includes a metal material portion 210 that is disposed below and in direct contact with the 2D material portion 21a, the semimetal material portion 21d, the metal material portion 21e, the metal material portion 21f and the semimetal material portion 21g, and that is disposed above and in direct contact with the first dielectric layer 10 and the metal material portion 11a. The material for the metal material portion 210 may be the same as or similar to that for the metal material portion 11a (as described in step S02), and thus details thereof are omitted for the sake of brevity. In some embodiments, the metal material portion 210 may be formed in the recess of the second dielectric layer 20 before formation of other portions (e.g., the 2D material portion 21a, etc.) of the second conductive feature 21.

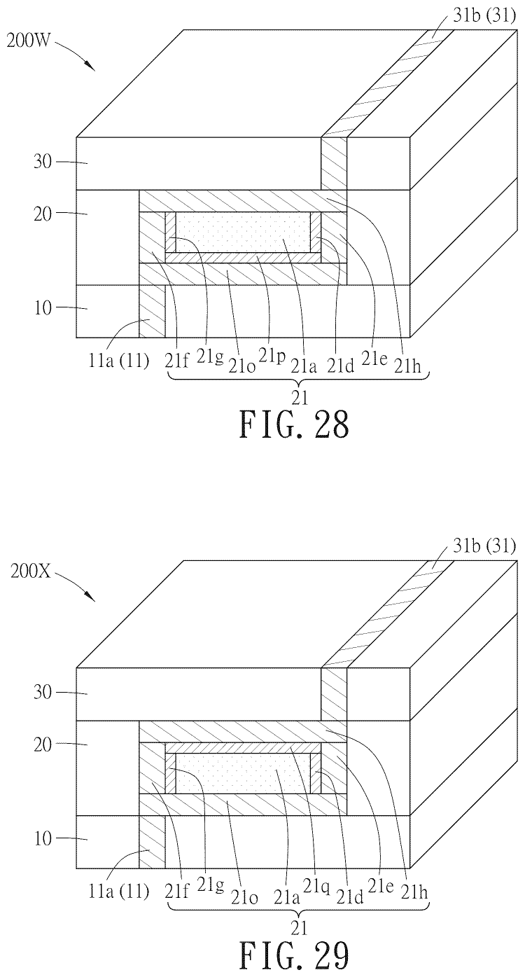

FIG. 28 illustrates a schematic view of a semiconductor structure 200W in accordance with some embodiments. A configuration of the semiconductor structure 200W is similar to that of the semiconductor structure 200V (see FIG. 27) except that, the second conductive feature 21 further includes a semimetal material portion 21p that is disposed below and in direct contact with the 2D material portion 21a, the semimetal material portion 21d and the semimetal material portion 21g, and that is disposed above and in direct contact with the metal material portion 210. The material for the semimetal material portion 21p may be the same as or similar to that for the semimetal material portion 11b (as described in step S02), and thus details thereof are omitted for the sake of brevity. In some embodiments, the semimetal material portion 21p may be selectively formed on the metal material portion 210 and in the recess of the second dielectric layer 20 after formation of the metal material portion 210 and before the formation of the 2D material portion 21a.

FIG. 29 illustrates a schematic view of a semiconductor structure 200X in accordance with some embodiments. A configuration of the semiconductor structure 200X is similar to that of the semiconductor structure 200V (see FIG. 27) except that, the second conductive feature 21 further includes a semimetal material portion 21q that is disposed above and in direct contact with the 2D material portion 21a, the semimetal material portion 21d and the semimetal material portion 21g, and that is disposed below and in direct contact with the metal material portion 21h. The material for the semimetal material portion 21q may be the same as or similar to that for the semimetal material portion 11b (as described in step S02), and thus details thereof are omitted for the sake of brevity. In some embodiments, the semimetal material portion 21q may be selectively formed on the 2D material portion 21a, the semimetal material portion 21d and the semimetal material portion 21g and in the recess of the second dielectric layer 20 after the formation of the 2D material portion 21a, the semimetal material portion 21d and the semimetal material portion 21g, and before the formation of the metal material portion 21h.

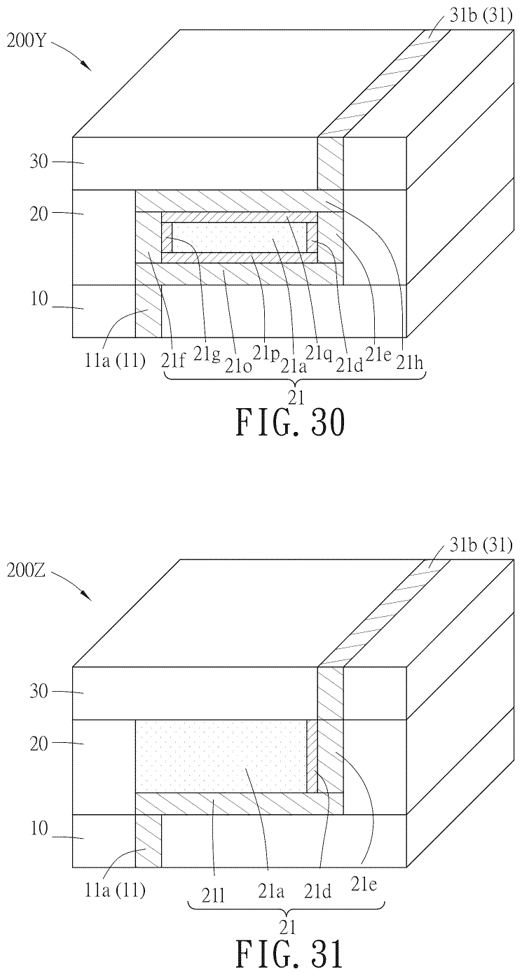

FIG. 30 illustrates a schematic view of a semiconductor structure 200Y in accordance with some embodiments. A configuration of the semiconductor structure 200Y is similar to that of the semiconductor structure 200V (see FIG. 27) except that, the second conductive feature 21 further includes the semimetal material portion 21p (see FIG. 28) and the semimetal material portion 21q (see FIG. 29). The material and process for each of the semimetal material portions 21p, 21q are described in the foregoing paragraphs, and thus details thereof are omitted for the sake of brevity.

FIG. 31 illustrates a schematic view of a semiconductor structure 200Z in accordance with some embodiments. A configuration of the semiconductor structure 200Z is similar to that of the semiconductor structure 200T (see FIG. 25) except that, the second conductive feature 21 includes the 2D material portion 21a, the semimetal material portion 21d, the metal material portion 21e and the metal material portion 211 without the metal material portion 21f and the semimetal material portion 21g.

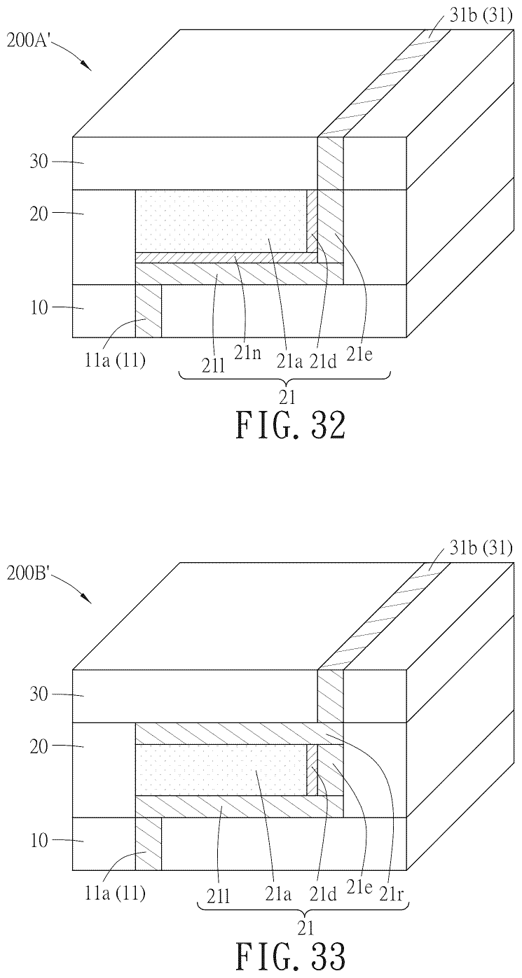

FIG. 32 illustrates a schematic view of a semiconductor structure 200A′ in accordance with some embodiments. A configuration of the semiconductor structure 200A′ is similar to that of the semiconductor structure 200U (see FIG. 26) except that, the second conductive feature 21 includes the 2D material portion 21a, the semimetal material portion 21d, the metal material portion 21e, the metal material portion 211 and the semimetal material portion 21n without the metal material portion 21f and the semimetal material portion 21g.

FIG. 33 illustrates a schematic view of a semiconductor structure 200B′ in accordance with some embodiments. A configuration of the semiconductor structure 200B′ is similar to that of the semiconductor structure 200Z (see FIG. 31) except that, the second conductive feature 21 further includes a metal material portion 21r that is disposed above and in direct contact with the 2D material portion 21a, the semimetal material portion 21d and the metal material portion 21e, and that is disposed below and in direct contact with the third dielectric layer 30 and the metal material portion 31b. The material for the metal material portion 21r may be the same as or similar to that for the metal material portion 11a (as described in step S02), and thus details thereof are omitted for the sake of brevity. In some embodiments, the metal material portion 21r may be formed on the 2D material portion 21a, the semimetal material portion 21d and the metal material portion 21e and in the recess of the second dielectric layer 20 after the formation of the 2D material portion 21a, the semimetal material portion 21d and the metal material portion 21e, and before the formation of the third dielectric layer 30.

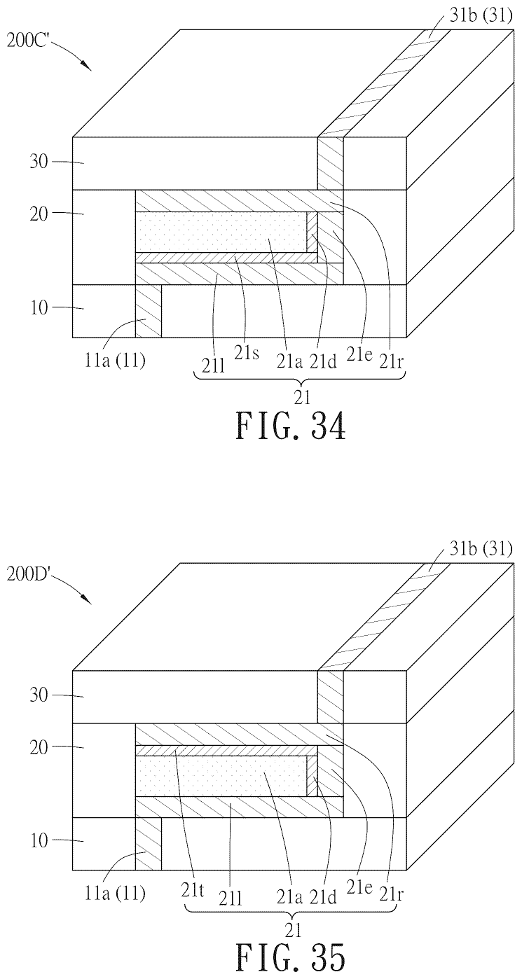

FIG. 34 illustrates a schematic view of a semiconductor structure 200C′ in accordance with some embodiments. A configuration of the semiconductor structure 200C′ is similar to that of the semiconductor structure 200B′ (see FIG. 33) except that, the second conductive feature 21 further includes a semimetal material portion 21s that is disposed below and in direct contact with the 2D material portion 21a and the semimetal material portion 21d, and that is disposed above and in direct contact with the metal material portion 211. The material for the semimetal material portion 21s may be the same as or similar to that for the semimetal material portion 11b (as described in step S02), and thus details thereof are omitted for the sake of brevity. In some embodiments, the semimetal material portion 21s may be selectively formed on the metal material portion 211 and in the recess of the second dielectric layer 20 after formation of the metal material portion 211, and before the formation of the 2D material portion 21a or the semimetal material portion 21d.

FIG. 35 illustrates a schematic view of a semiconductor structure 200D′ in accordance with some embodiments. A configuration of the semiconductor structure 200D′ is similar to that of the semiconductor structure 200B′ (see FIG. 33) except that, the second conductive feature 21 further includes a semimetal material portion 21t that is disposed below and in direct contact with the metal material portion 21r, and that is disposed above and in direct contact with the 2D material portion 21a and the semimetal material portion 21d. The material for the semimetal material portion 21t may be the same as or similar to that for the semimetal material portion 11b (as described in step S02), and thus details thereof are omitted for the sake of brevity. In some embodiments, the semimetal material portion 21t may be selectively formed on the 2D material portion 21a and the semimetal material portion 21d and in the recess of the second dielectric layer 20 after the formation of the 2D material portion 21a and the semimetal material portion 21d, and before formation of the metal material portion 21r.

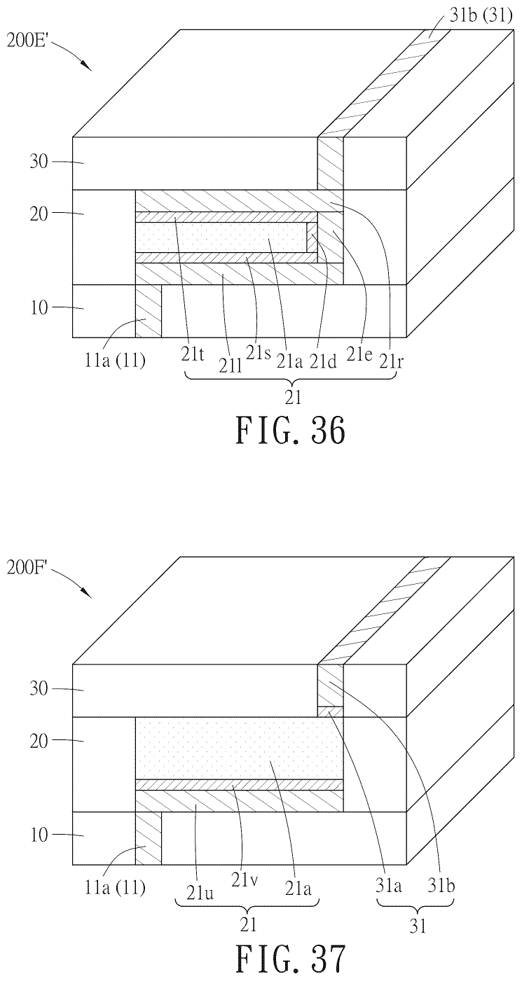

FIG. 36 illustrates a schematic view of a semiconductor structure 200E′ in accordance with some embodiments. A configuration of the semiconductor structure 200E′ is similar to that of the semiconductor structure 200B′ (see FIG. 33) except that, the second conductive feature 21 further includes the semimetal material portion 21s (see FIG. 34) and the semimetal material portion 21t (see FIG. 35). The material and process for each of the semimetal material portions 21s, 21t are described in the foregoing paragraphs, and thus details thereof are omitted for the sake of brevity.

FIG. 37 illustrates a schematic view of a semiconductor structure 200F′ in accordance with some embodiments. A configuration of the semiconductor structure 200F′ is similar to that of the semiconductor structure 200A (see FIG. 7) except that, the first conductive feature 11 includes the metal material portion 11a without any semimetal material portion (for example, the semimetal material portion 11b shown in FIG. 7), and the second conductive feature 21 further includes a metal material portion 21u and a semimetal material portion 21v. The metal material portion 21u is disposed above and in direct contact with the first dielectric layer 10 and the metal material portion 11a. The material and process for the metal material portion 21u may be the same as or similar to those for the metal material portion 11a (as described in step S02), and thus details thereof are omitted for the sake of brevity. The semimetal material portion 21v is disposed on the metal material portion 21u opposite to the first dielectric layer 10. The semimetal material portion 21v is disposed between and in direct contact with the 2D material portion 21a and the metal material portion 21u. The material and process for the semimetal material portion 21v may be the same as or similar to those for the semimetal material portion 11b (as described in step S02), and thus details thereof are omitted for the sake of brevity. In this case, the 2D material portion 21a is disposed on the semimetal material portion 21v opposite to the metal material portion 21u.

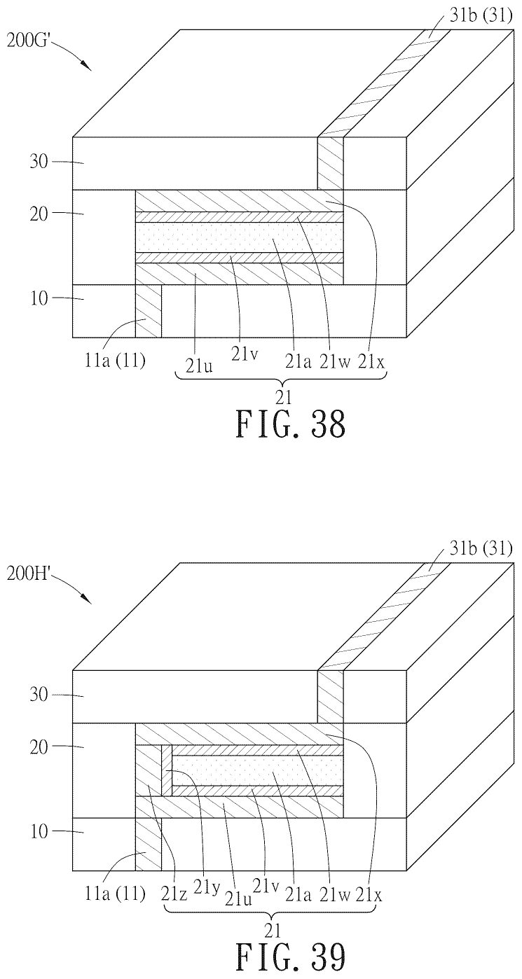

FIG. 38 illustrates a schematic view of a semiconductor structure 200G′ in accordance with some embodiments. A configuration of the semiconductor structure 200G′ is similar to that of the semiconductor structure 200F′ (see FIG. 37) except that, the second conductive feature 21 further includes a semimetal material portion 21w and a metal material portion 21x, and the third conductive feature 31 includes the metal material portion 31b without any semimetal material portion (for example, the semimetal material portion 31a shown in FIG. 37). The semimetal material portion 21w is disposed on the 2D material portion 21a opposite to the semimetal material portion 21v. The metal material portion 21x is disposed on the semimetal material portion 21w opposite to the 2D material portion 21a, and is disposed below and in direct contact with the third dielectric layer 30 and the metal material portion 31b. The semimetal material portion 21w is disposed between and in direct contact with the 2D material portion 21a and the metal material portion 21x. The material for each of the semimetal material portion 21w and the metal material portion 21x may be the same as or similar to that for a corresponding one of the semimetal material portion 11b and the metal material portion 11a (as described in step S02), and thus details thereof are omitted for the sake of brevity. In some embodiments, the semimetal material portion 21w and the metal material portion 21x may be sequentially formed in the recess of the second dielectric layer 20 after the formation of the 2D material portion 21a, and before the formation of the third dielectric layer 30.

FIG. 39 illustrates a schematic view of a semiconductor structure 200H′ in accordance with some embodiments. A configuration of the semiconductor structure 200H′ is similar to that of the semiconductor structure 200G′ (see FIG. 38) except that, the second conductive feature 21 further includes a semimetal material portion 21y and a metal material portion 21z. The semimetal material portion 21y is disposed on a lateral side of each of the 2D material portion 21a, the semimetal material portion 21v, and the semimetal material portion 21w. The metal material portion 21z is disposed between the semimetal material portion 21y and the second dielectric layer 20. The semimetal material portion 21y is disposed between and in direct contact with the 2D material portion 21a and the metal material portion 21z. The material for each of the semimetal material portion 21y and the metal material portion 21z may be the same as or similar to that for a corresponding one of the semimetal material portion 11b and the metal material portion 11a (as described in step S02), and thus details thereof are omitted for the sake of brevity. In some embodiments, the semimetal material portion 21y and the metal material portion 21z may be sequentially formed in the recess of the second dielectric layer 20 after the formation of the 2D material portion 21a, the semimetal material portion 21v and the semimetal material portion 21w, and before formation of the metal material portion 21x.

In a semiconductor structure of this disclosure, by having at least one of semimetal material portion disposed, for example, but not limited to, between a metal material portion of a first conductive feature and a 2D material portion of a second conductive feature, and/or between the 2D material portion of the second conductive feature and a metal material portion of a third conductive feature, a contact resistance (Rc) between the metal material portion of the first conductive feature and the 2D material portion of the second conductive feature, and/or a contact resistance (Rc) between the 2D material portion of the second conductive feature and the metal material portion of the third conductive feature may be efficiently reduced, which is conducive to enhancing electrical performance of the semiconductor structure.

In accordance with some embodiments of the present disclosure, a semiconductor structure includes a substrate, a dielectric structure, and an interconnect structure. The dielectric structure includes a first dielectric layer disposed on the substrate and a second dielectric layer disposed on the first dielectric layer opposite to the substrate. The interconnect structure is configured with a first conductive feature disposed in the first dielectric layer and a second conductive feature that is disposed in the second dielectric layer and that is connected to the first conductive feature, and includes a first metal material portion, a two-dimensional material portion, and a first semimetal material portion disposed between and connected to the first metal material portion and the two-dimensional material portion.

In accordance with some embodiments of the present disclosure, the second conductive feature includes the first metal material portion, the two-dimensional material portion and the first semimetal material portion, and further includes a second metal material portion disposed on the two-dimensional material portion opposite to the first metal material portion, and a second semimetal material portion disposed between and connected to the two-dimensional material portion and the second metal material portion.

In accordance with some embodiments of the present disclosure, the first conductive feature further includes a third semimetal material portion disposed in the first dielectric layer and connected to the second semimetal material portion.

In accordance with some embodiments of the present disclosure, the second conductive feature further includes a third metal material portion disposed on the two-dimensional material portion, the first semimetal material portion, the first metal material portion, the second metal material portion, and the second semimetal material portion.

In accordance with some embodiments of the present disclosure, the first conductive feature further includes a third semimetal material portion disposed in the first dielectric layer, and connected to the second semimetal material portion.

In accordance with some embodiments of the present disclosure, the second conductive feature further includes a third semimetal material portion disposed between the two-dimensional material portion and the third metal material portion.

In accordance with some embodiments of the present disclosure, the first conductive feature further includes a fourth semimetal material portion disposed in the first dielectric layer, and connected to the second semimetal material portion.

In accordance with some embodiments of the present disclosure, each of the first semimetal material portion, the second semimetal material portion, the third semimetal material portion, and the fourth semimetal material portion includes bismuth, antimony, tin, or combinations thereof.

In accordance with some embodiments of the present disclosure, a semiconductor structure includes a substrate, a dielectric structure, and an interconnect structure. The dielectric structure includes a first dielectric layer disposed on the substrate, a second dielectric layer disposed on the first dielectric layer opposite to the substrate, and a third dielectric layer disposed on the second dielectric layer opposite to the first dielectric layer. The interconnect structure is configured with a first conductive feature disposed in the first dielectric layer, a second conductive feature disposed in the second dielectric layer and connected to the first conductive feature, and a third conductive feature disposed in the third dielectric layer and connected to the second conductive feature, and includes a first metal material portion, a two-dimensional material portion, and a first semimetal material portion disposed between and connected to the first metal material portion and the two-dimensional material portion.

In accordance with some embodiments of the present disclosure, the second conductive feature includes the first metal material portion, the two-dimensional material portion and the first semimetal material portion, and further includes a second metal material portion disposed on the two-dimensional material portion opposite to the first metal material portion, and a second semimetal material portion disposed between and connected to the two-dimensional material portion and the second metal material portion.

In accordance with some embodiments of the present disclosure, the third conductive feature further includes a third semimetal material portion disposed in the third dielectric layer and connected to the first semimetal material portion.

In accordance with some embodiments of the present disclosure, the second conductive feature further includes a third metal material portion that is disposed between the first dielectric layer and the two-dimensional material portion, and that is connected to the two-dimensional material portion, the first metal material portion, the second metal material portion, the first semimetal material portion, and the second semimetal material portion.

In accordance with some embodiments of the present disclosure, the second conductive feature further includes a third semimetal material portion disposed between and connected to the two-dimensional material portion and the third metal material portion.

In accordance with some embodiments of the present disclosure, the second conductive feature further includes a third metal material portion disposed between the first dielectric layer and the two-dimensional material portion, and a fourth metal material portion disposed between the two-dimensional material portion and the third dielectric layer.

In accordance with some embodiments of the present disclosure, the second conductive feature further includes a third semimetal material portion disposed between the two-dimensional material portion and the third metal material portion.

In accordance with some embodiments of the present disclosure, the second conductive feature further includes a third semimetal material portion disposed between the two-dimensional material portion and the fourth metal material portion.

In accordance with some embodiments of the present disclosure, the second conductive feature further includes a third semimetal material portion disposed between the two-dimensional material portion and the third metal material portion, and a fourth semimetal material portion disposed between the two-dimensional material portion and the fourth metal material portion.

In accordance with some embodiments of the present disclosure, a method for manufacturing a semiconductor structure includes: forming a first dielectric layer on a substrate; forming a first conductive feature in the first dielectric layer; forming a second dielectric layer on the first dielectric layer and the first conductive feature opposite to the substrate; and forming a second conductive feature in the second dielectric layer so as to obtain an interconnect structure which is configured with the first conductive feature and the second conductive feature that is connected to the first conductive feature, and which includes a first metal material portion, a two-dimensional material portion, and a first semimetal material portion disposed between and connected to the first metal material portion and the two-dimensional material portion.

In accordance with some embodiments of the present disclosure, the second conductive feature includes the first metal material portion, the two-dimensional material portion, and the first semimetal material portion, and further includes a second metal material portion disposed on the two-dimensional material portion opposite to the first metal material portion, and a second semimetal material portion disposed between and connected to the two-dimensional material portion and the second metal material portion. The first conductive feature includes a third metal material portion disposed below and connected to the second metal material portion.

In accordance with some embodiments of the present disclosure, the method for manufacturing the semiconductor structure further includes forming a third dielectric layer on the second dielectric layer opposite to the first dielectric layer, and forming a third conductive feature in the third dielectric layer. The third conductive feature is connected to the second conductive feature and includes a fourth metal material portion disposed on and connected to the first metal material portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a dielectric structure including a first dielectric layer disposed on the substrate and a second dielectric layer disposed on the first dielectric layer opposite to the substrate; and
an interconnect structure which is configured with a first conductive feature disposed in the first dielectric layer and a second conductive feature that is disposed in the second dielectric layer and that is connected to the first conductive feature, and which includes a first metal material portion, a two-dimensional material portion, and a first semimetal material portion disposed between and connected to the first metal material portion and the two-dimensional material portion.

2. The semiconductor structure as claimed in claim 1, wherein
the second conductive feature includes the first metal material portion, the two-dimensional material portion, and the first semimetal material portion; and
the second conductive feature further includes a second metal material portion disposed on the two-dimensional material portion opposite to the first metal material portion, and a second semimetal material portion disposed between and connected to the two-dimensional material portion and the second metal material portion.

3. The semiconductor structure as claimed in claim 2, wherein the first conductive feature further includes a third semimetal material portion disposed in the first dielectric layer, and connected to the second semimetal material portion.

4. The semiconductor structure as claimed in claim 2, wherein the second conductive feature further includes a third metal material portion disposed on the two-dimensional material portion, the first semimetal material portion, the first metal material portion, the second metal material portion, and the second semimetal material portion.

5. The semiconductor structure as claimed in claim 4, wherein the first conductive feature further includes a third semimetal material portion disposed in the first dielectric layer, and connected to the second semimetal material portion.

6. The semiconductor structure as claimed in claim 4, wherein the second conductive feature further includes a third semimetal material portion disposed between the two-dimensional material portion and the third metal material portion.

7. The semiconductor structure as claimed in claim 6, wherein the first conductive feature further includes a fourth semimetal material portion disposed in the first dielectric layer, and connected to the second semimetal material portion.

8. The semiconductor structure as claimed in claim 7, wherein each of the first semimetal material portion, the second semimetal material portion, the third semimetal material portion, and the fourth semimetal material portion includes bismuth, antimony, tin, or combinations thereof.

9. A semiconductor structure, comprising:
a substrate;
a dielectric structure including a first dielectric layer disposed on the substrate, a second dielectric layer disposed on the first dielectric layer opposite to the substrate, and a third dielectric layer disposed on the second dielectric layer opposite to the first dielectric layer; and
an interconnect structure which is configured with a first conductive feature disposed in the first dielectric layer, a second conductive feature disposed in the second dielectric layer and connected to the first conductive feature, and a third conductive feature disposed in the third dielectric layer and connected to the second conductive feature, and which includes a first metal material portion, a two-dimensional material portion, and a first semimetal material portion disposed between and connected to the first metal material portion and the two-dimensional material portion.

10. The semiconductor structure as claimed in claim 9, wherein
the second conductive feature includes the first metal material portion, the two-dimensional material portion, and the first semimetal material portion; and
the second conductive feature further includes a second metal material portion disposed on the two-dimensional material portion opposite to the first metal material portion, and a second semimetal material portion disposed between and connected to the two-dimensional material portion and the second metal material portion.

11. The semiconductor structure as claimed in claim 10, wherein the third conductive feature further includes a third semimetal material portion disposed in the third dielectric layer, and connected to the first semimetal material portion.

12. The semiconductor structure as claimed in claim 10, wherein the second conductive feature further includes a third metal material portion that is disposed between the first dielectric layer and the two-dimensional material portion, and that is connected to the two-dimensional material portion, the first metal material portion, the second metal material portion, the first semimetal material portion, and the second semimetal material portion.

13. The semiconductor structure as claimed in claim 12, wherein the second conductive feature further includes a third semimetal material portion disposed between and connected to the two-dimensional material portion and the third metal material portion.

14. The semiconductor structure as claimed in claim 10, wherein the second conductive feature further includes a third metal material portion disposed between the first dielectric layer and the two-dimensional material portion, and a fourth metal material portion disposed between the two-dimensional material portion and the third dielectric layer.

15. The semiconductor structure as claimed in claim 14, wherein the second conductive feature further includes a third semimetal material portion disposed between the two-dimensional material portion and the third metal material portion.

16. The semiconductor structure as claimed in claim 14, wherein the second conductive feature further includes a third semimetal material portion disposed between the two-dimensional material portion and the fourth metal material portion.

17. The semiconductor structure as claimed in claim 14, wherein the second conductive feature further includes a third semimetal material portion disposed between the two-dimensional material portion and the third metal material portion, and a fourth semimetal material portion disposed between the two-dimensional material portion and the fourth metal material portion.

18. A method for manufacturing a semiconductor structure, comprising:
forming a first dielectric layer on a substrate;
forming a first conductive feature in the first dielectric layer;
forming a second dielectric layer on the first dielectric layer and the first conductive feature opposite to the substrate; and
forming a second conductive feature in the second dielectric layer so as to obtain an interconnect structure which is configured with the first conductive feature and the second conductive feature that is connected to the first conductive feature, and which includes a first metal material portion, a two-dimensional material portion, and a first semimetal material portion disposed between and connected to the first metal material portion and the two-dimensional material portion.

19. The method as claimed in claim 18, wherein
the second conductive feature includes the first metal material portion, the two-dimensional material portion, and the first semimetal material portion, and further includes a second metal material portion disposed on the two-dimensional material portion opposite to the first metal material portion, and a second semimetal material portion disposed between and connected to the two-dimensional material portion and the second metal material portion; and
the first conductive feature includes a third metal material portion disposed below and connected to the second metal material portion.

20. The method as claimed in claim 18, further comprising:
forming a third dielectric layer on the second dielectric layer opposite to the first dielectric layer, and
forming a third conductive feature in the third dielectric layer, the third conductive feature being connected to the second conductive feature and including a fourth metal material portion disposed on and connected to the first metal material portion.
